(19) United States
(12) Patent Application Publication
(10) Pub. No.: US 2008/0284538 A1
(43) Pub. Date: Nov. 20, 2008

(54) PRINTED CIRCUIT BOARD

(75) Inventor: SHOU-KUO HSU, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/834,705

(22) Filed: Aug. 7, 2007

(30) Foreign Application Priority Data
May 18, 2007 (CN) 200710200647.9

(51) Int. Cl. H03H 7/38

(52) U.S. Cl. 333/124

(57) ABSTRACT

A printed circuit board includes a signal layer, a first reference plane layer, and a second reference plane layer. At least one transmission line is arranged on the signal layer. The transmission line includes a main transmission line, and two branch transmission lines connected to an end of the main transmission line. The first reference plane layer is disposed below the signal layer for the main transmission line. The second reference plane layer is disposed below the first reference plane layer for the branch transmission lines, to increase impedance of the two branch transmission lines.

### BACKGROUND

1. Field of the Invention

The present invention relates to printed circuit boards (PCBs). In particular, the present invention relates to a printed circuit board which can improve impedance of signal transmission lines.

2. Description of Related Art

With the increasing speeds of integrated circuits (ICs), signal integrity is becoming one of the most important problems. Many factors, such as the parameters of the electrical elements or the PCB and the layout of the PCB, can affect the signal integrity, or lead to instability of the system, possibly even causing the system to breakdown. Thus, preserving signal integrity has become a key point in the design of a PCB.

Referring to FIG. 3, a typical four-layer PCB includes a microstrip line 10, which is a kind of transmission line arranged between the air and a dielectric layer 12. A plane layer 14 is located under the dielectric layer 12 as a reference plane of the microstrip line 10. The plane layer 14 can be a power layer or a ground layer. A formula used to calculate characteristic impedance of the microstrip line 10 is as follows:

$$Z = \frac{87}{\sqrt{ξ + 1.41}} ln ( \frac{5.98 H}{0.8 W + T} )$$

Where Z is the characteristic impedance of the microstrip line 10, ξ is the dielectric constant of the dielectric layer 12, H is the thickness of the dielectric layer 12, W is the width of the microstrip line 10, T is the thickness of the microstrip line 10.

In light of the formula, it can be seen that the characteristic impedance (Z) of the microstrip line 10 is directly proportional to the thickness of the dielectric layer 12 (H) and inversely proportional to the dielectric constant of the dielectric layer 12 (ξ), the width of the microstrip line 10 (W), and the thickness of the microstrip line 10 (T).

Referring to FIG. 4, a conventional transmission line, which is usually arranged in a PCB, includes a driving terminal 20, a main transmission line 22, two branch transmission lines 24, and two receiving terminals 26. One end of the main transmission line 22 is connected to the driving terminal 20. The other end of the main transmission line 22 is connected to a junction of the two branch transmission lines 24. The two receiving terminals 26 are connected to the two branch transmission lines 24 respectively. When the characteristic impedance of the main transmission line 22 does not match the characteristic impedance of the two branch transmission lines 24, part of the signal will be reflected at the two receiving terminals 26. Thus, the signal will be distorted, which can affect the signal integrity.

According to the foregoing formula, a conventional solution is to decrease the width of the branch transmission lines 24 to increase the impedance thereof to match the characteristic impedance of the main transmission line 22. However, restricted by the etching technology and cost, there is a limit to the narrowest width of the two branch transmission lines 24, thus it is difficult to accomplish the characteristic impedance match between the main transmission line 22 and the two branch transmission lines 24 by decreasing the width of the two branch transmission lines 24.

What is needed is a printed circuit board with improved impedance of signal transmission lines.

### SUMMARY

An exemplary printed circuit board includes a signal layer, a first reference plane layer, and a second reference plane layer. At least one transmission line is arranged on the signal layer. The transmission line includes a main transmission line, and two branch transmission lines connected to an end of the main transmission line. The first reference plane layer is disposed below the signal layer for the main transmission line. The second reference plane layer is disposed below the first reference plane layer for the branch transmission lines, to increase impedance of the two branch transmission lines.

Other advantages and novel features of the present invention will become more apparent from the following detailed description of embodiments when taken in conjunction with the accompanying drawings, in which:

### BRIEF DESCRIPTION OF THE DRAWINGS

FIG. 1 is a cross-sectional view of a printed circuit board in accordance with a first embodiment of the present invention;

FIG. 2 is a cross-sectional view of a printed circuit board in accordance with a second embodiment of the present invention;

FIG. 3 is a cross-sectional view of a conventional printed circuit board; and

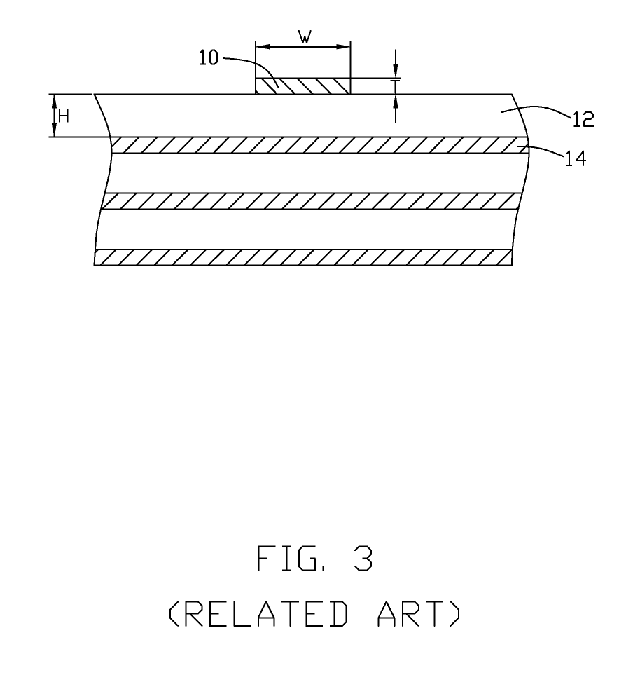

FIG. 4 is a schematic view of the structure assembly of a conventional transmission line.

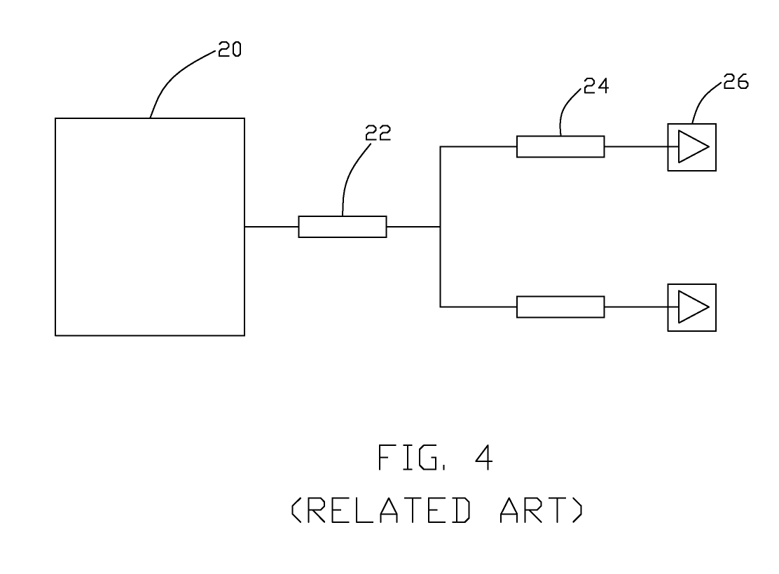

### DETAILED DESCRIPTION

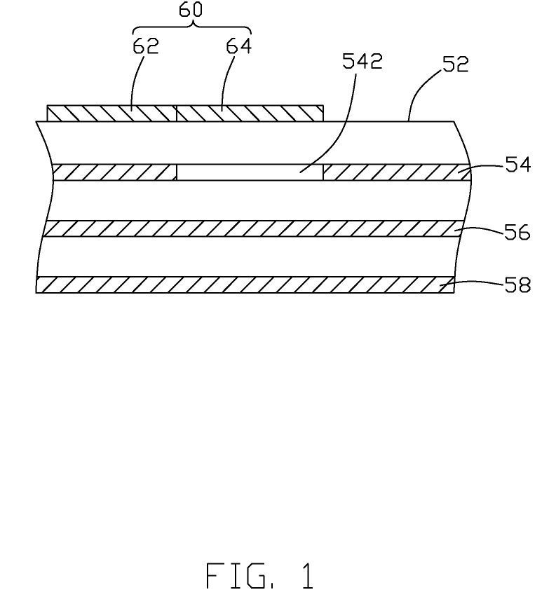

Referring to FIG. 1, a printed circuit board (PCB) according to a first embodiment of the present invention is described herein. In this embodiment, a four-layer PCB is employed to illustrate the invention. The four-layer PCB includes a first signal layer 52 having a transmission line 60 arranged thereon, a ground layer 54, a power layer 56, and a second signal layer 58 from the top down. In the FIG. 1, the shaded area of the four-layer PCB is composed of copper, and the other area is composed of dielectric material. The transmission line 60 includes a main transmission line 62, and two branch transmission lines 64 connected to an end of the main transmission line 62. The two branch transmission lines 64 are the same length.

A void 542 is defined in the ground layer 54 under each of the two branch transmission lines 64 of the transmission line 60. The void 542 allows the power layer 56 to act as the reference plane for the branch lines 64. Elsewhere, beneath the transmission line 60, the ground layer 54 acts as the reference plane. Thus, the distance between the branch transmission lines 64 and the power layer 56 is greater than if the ground layer 54 were the reference plane. According to the formula to calculate characteristic impedance of the microstrip line, the increased distance between the two branch transmission lines 64 and its present reference plane (the power layer 56) means increased thickness of the dielectric layer under the two branch transmission lines 64. That is, the characteristic impedance of the branch transmission lines 64 is increased.

In addition, the width of the branch transmission lines 64 of the transmission line 60 can be easily adjusted to further increase the characteristic impedance of the branch transmission lines 64 to achieve impedance match between the main transmission line 62 and the two branch transmission lines 64. Thus, signal integrity is improved.

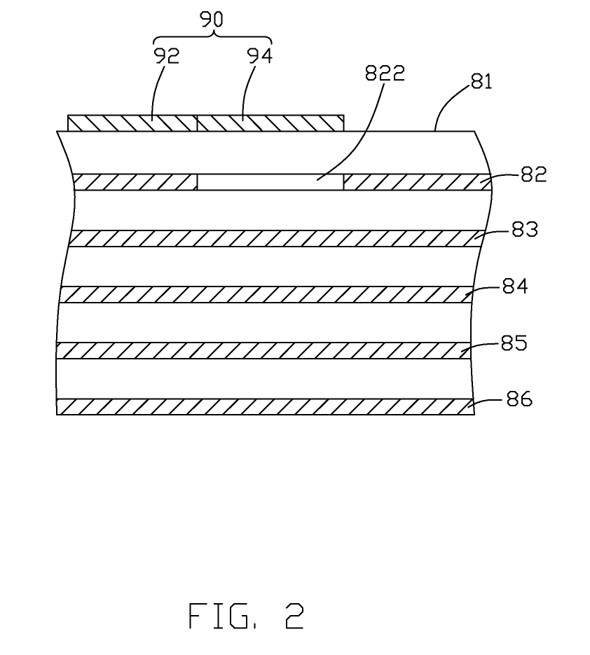

Referring to FIG. 2, a PCB according to a second embodiment of the present invention is described herein. In this embodiment, a six-layer PCB is employed to illustrate the invention. The six-layer PCB includes a first signal layer 81 having a transmission line 90 arranged thereon, a first ground layer 82, a second signal layer 83, a second ground layer 84, a power layer 85, and a third signal layer 86 from the top down. The transmission line 90 includes a main transmission line 92, and two branch transmission lines 94 connected to an end of the main transmission line 92. The two branch transmission lines 94 are the same length.

A void 822 is defined in the ground layer 82 under the two branch transmission lines 94 of the transmission line 90. The void 822 allows the second ground layer 84 to act as the reference plane for the branch lines 94. Elsewhere, beneath the transmission line 90, the first ground layer 82 acts as the reference plane. Thus, the distance between the branch transmission lines 94 and the second ground layer 84 is greater than if the first ground layer 82 were the reference plane. According to the formula to calculate characteristic impedance of the microstrip line, the increased distance between the two branch transmission lines 94 and its present reference plane (second ground layer 84) means increased thickness of the dielectric layer under the two branch transmission lines 94. That is, the characteristic impedance of the branch transmission lines 94 is increased. In addition, the width of the branch transmission lines 94 of the transmission line 90 can be easily adjusted to further increase the characteristic impedance of the branch transmission lines 94 to achieve impedance match between the main transmission line 92 and the two branch transmission lines 94. Thus, signal integrity is improved.

In the embodiments of the present invention, a stitching via can be defined in one of the reference planes electrically connected to the reference plane if it is needed to reduce noise and a cross talk in the transmission line.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A printed circuit board comprising:
a signal layer, at least one transmission line arranged thereon, the transmission line comprising a main transmission line, and two branch transmission lines connected to an end of the main transmission line;
a first reference plane layer for the main transmission line disposed below the signal layer; and
a second reference plane layer for the branch transmission lines disposed below the first reference plane layer, to increase impedance of the two branch transmission lines.

2. The printed circuit board as described in claim 1, wherein the first reference plane layer is a power layer or a ground layer.

3. The printed circuit board as described in claim 1, wherein the second reference plane layer is a power layer or a ground layer.

4. The printed circuit board as described in claim 1, wherein the two branch transmission lines of the transmission line are the same length.

5. A printed circuit board comprising:
a first electrically conductive layer having at least one transmission line arranged thereon, the at least one transmission line comprising a main transmission line, and two branch transmission lines connected to an end of the main transmission line;
a second electrically conductive layer disposed below the first conductive layer; and
a third electrically conductive layer disposed below the second conductive layer;
void being defined through the second conductive layer under each of the branch transmission lines to allow the third conductive layer acting as a reference plane for the branch lines while the second conductive layer acting as a reference plane for the main transmission line.

6. The printed circuit board as described in claim 5, wherein the first conductive layer is a signal layer.

7. The printed circuit board as described in claim 6, wherein the second conductive layer is a ground layer.

8. The printed circuit board as described in claim 7, wherein the third conductive layer is another ground layer.

9. The printed circuit board as described in claim 7, wherein the third conductive layer is a power layer.

10. The printed circuit board as described in claim 7, wherein the two branch transmission lines have the same length.
